(19) United States
(12) Patent Application Publication
(10) Pub. No.: US 2017/0178797 A1
(43) Pub. Date: Jun. 22, 2017

(54) Surface Mount Inductor for Placement Over a Power Stage of a Power Converter

(71) Applicant: Infineon Technologies Austria AG, Villach (AT)

(72) Inventor: Emil Todorov, Fremont, CA (US)

(21) Appl. No.: 14/977,141

(22) Filed: Dec. 21, 2015

(51) Int. Cl. H01F 27/29; H05K 3/30; H01F 30/12; H05K 1/18

(52) U.S. Cl. CPC H01F 27/292; H05K 1/181; H05K 3/301; H01F 30/12

(57) ABSTRACT

An electrical conductor of a surface mount inductor includes a first section extending along a first side face of the magnetic core, a second section extending along a second side face of the magnetic core, and a third section connecting the first and second sections and extending through the magnetic core. A first straight lead extends downwards from the first section beyond the bottom main face of the magnetic core, and has an unbent distal end configured for surface mounting to a circuit board. A second straight lead extends downwards from the second section beyond the bottom main face, and has an unbent distal end configured for surface mounting to the circuit board. The straight leads each have a height and a width which allows for mounting of a power stage to the circuit board at least partly under the magnetic core.

### TECHNICAL FIELD

The instant application relates to power converters, and more particularly to surface mount inductors for power converters.

### BACKGROUND

Power converters such as DC-DC converters include several active and passive components, including a power stage for regulating the voltage of a load such as a processor. The power stage is coupled to the load by an output inductor. The components of a power converter, including the output inductor, are attached to a printed circuit board (PCB) together with the load. The PCB has various electrical pathways for electrically interconnecting the components of the power converter, and electrically connecting the power stage of the converter to the load. The power stages are conventionally attached to the PCB in the same plane as the output inductor, increasing the size of the PCB. Also, conventional layout design practices for PCBs further complicate such an arrangement of the power converter components.

### SUMMARY

According to an embodiment of a surface mount inductor for placement over a power stage of a power converter, the surface mount inductor comprises a first electrical conductor and a magnetic core having top and bottom main faces and side faces extending between the top and bottom main faces. The first electrical conductor comprises a first section extending along a first one of the side faces of the magnetic core, a second section extending along a second one of the side faces opposite the first side face, and a third section connecting the first and second sections and extending through the magnetic core. The first electrical conductor also comprises a first straight lead extending downwards from the first section beyond the bottom main face of the magnetic core, and a second straight lead extending downwards from the second section beyond the bottom main face of the magnetic core. The first straight lead has an unbent distal end configured for surface mounting to a circuit board. The second straight lead also has an unbent distal end configured for surface mounting to the circuit board. The first and second straight leads each have a height and a width which allows for the power stage to be mounted to the circuit board at least partly under the magnetic core.

According to an embodiment of a power converter assembly, the power converter assembly comprises a circuit board having a first side and a second side opposite the first side, a power stage die of a power converter attached to the first side of the circuit board, and a surface mount inductor electrically connected to an output of the power stage die and disposed over the power stage die on the first side of the circuit board. The surface mount inductor comprises a first electrical conductor and a magnetic core having top and bottom main faces and side faces extending between the top and bottom main faces. The first electrical conductor comprises a first section extending along a first one of the side faces of the magnetic core, a second section extending along a second one of the side faces opposite the first side face, and a third section connecting the first and second sections and extending through the magnetic core. The first electrical conductor also comprises a first straight lead extending downwards from the first section beyond the bottom main face of the magnetic core, and a second straight lead extending downwards from the second section beyond the bottom main face of the magnetic core. The first straight lead has an unbent distal end surface mounted to the circuit board. The second straight lead also has an unbent distal end surface mounted to the circuit board. The first and second straight leads each have a height and a width which allows for the power stage to be mounted to the circuit board at least partly under the magnetic core.

According to an embodiment of a method of manufacturing a power converter assembly, the method comprises attaching a power stage die of a power converter to a first side of a circuit board and attaching a surface mount inductor to the first side of the circuit board so that the surface mount inductor is electrically connected to an output of the power stage die and disposed over the power stage die on the first side of the circuit board. The surface mount inductor comprises a magnetic core and a first electrical conductor. The first electrical conductor comprises: a first section extending along a first side face of the magnetic core; a second section extending along a second side face of the magnetic core; a third section connecting the first and second sections and extending through the magnetic core; a first straight lead extending downwards from the first section beyond a bottom main face of the magnetic core and having an unbent distal end; and a second straight lead extending downwards from the second section beyond the bottom main face of the magnetic core and having an unbent distal end, the first and second straight leads each having a height and a width which allows for the power stage to be mounted to the circuit board at least partly under the magnetic core. The surface mount inductor is attached to the first side of the circuit board by attaching the unbent distal end of the first and second straight leads to respective electrically conductive contact regions at the first side of the circuit board after the power stage die is attached to the first side of the circuit board, one of the electrically conductive contact regions being electrically connected to the output of the power stage die.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A through 1F illustrate different views of a surface mount inductor shaped to accommodate a power stage die of a power converter under the inductor.

FIG. 2 illustrates a side perspective view of a magnetic core included in a surface mount inductor shaped to accommodate a power stage die of a power converter under the inductor.

FIGS. 3A through 3D illustrate different views of an electrical conductor for use with the magnetic core shown in FIG. 2.

FIG. 4 illustrates a side view of a surface mount inductor shaped to accommodate a power stage die of a power converter under the inductor, according to another embodiment.

FIG. 5 illustrates a top plan view of a power converter assembly that includes one or more surface mount inductors shaped to accommodate a power stage die of the power converter assembly under the inductors.

FIG. 6 illustrates a side perspective view of a 2-phase surface mount inductor shaped to accommodate two power stages dies of two powerconverters placed completely or partially under the inductor.

FIG. 7 illustrates a side perspective view of a 2-phase surface mount inductor shaped to accommodate two power stages die of a two-phase power converter under the inductor, according to another embodiment.

FIG. 8A illustrates a side perspective view of an embodiment of a non-coupled 2-phase surface mount inductor shaped to accommodate two power stages dies of two power converters placed completely or partially under the inductor.

FIG. 8B illustrates a side perspective view of an embodiment of a coupled 2-phase surface mount inductor shaped to accommodate two power stages dies of two power converters placed completely or partially under the inductor.

### DETAILED DESCRIPTION

According to embodiments described herein, each power stage die of a power converter such as a DC-DC converter is placed under the corresponding output inductor for that power stage e.g. in a buck topology in order to reduce the overall size of the power converter solution. Each power stage provides an output phase of the converter to a load. In the case of a single-phase DC-DC non-isolated converter, a single power stage is provided. In the case of a multi-phase DC-DC non-isolated converter, a power stage is provided for each phase of the converter. Each power stage die delivers a phase current through an output inductor to the load regulated by the power converter. Each power stage die can have a high-side transistor and a low-side transistor for coupling to the load through the corresponding output inductor. The high-side transistor of each power stage switchably connects the load to an input voltage of the power converter and the corresponding low-side transistor switchably connects the load to ground at different periods. Each power stage die can include active semiconductor components such as MOSFETs (metal oxide semiconductor field effect transistors), drivers, etc. and corresponding passive components. The passive components can be excluded from the die and provided as separate components. In general, each power stage die includes at least the active semiconductor components used to provide an output phase of the power converter to the load and is placed under the corresponding output inductor when attached to a circuit board such as a PCB to form a power converter assembly. The power stage die is not limited to a monolithic, single die power stage, but can also include an integrated package containing one or more dies including but not limited to the driver, the high side and the low side FET.

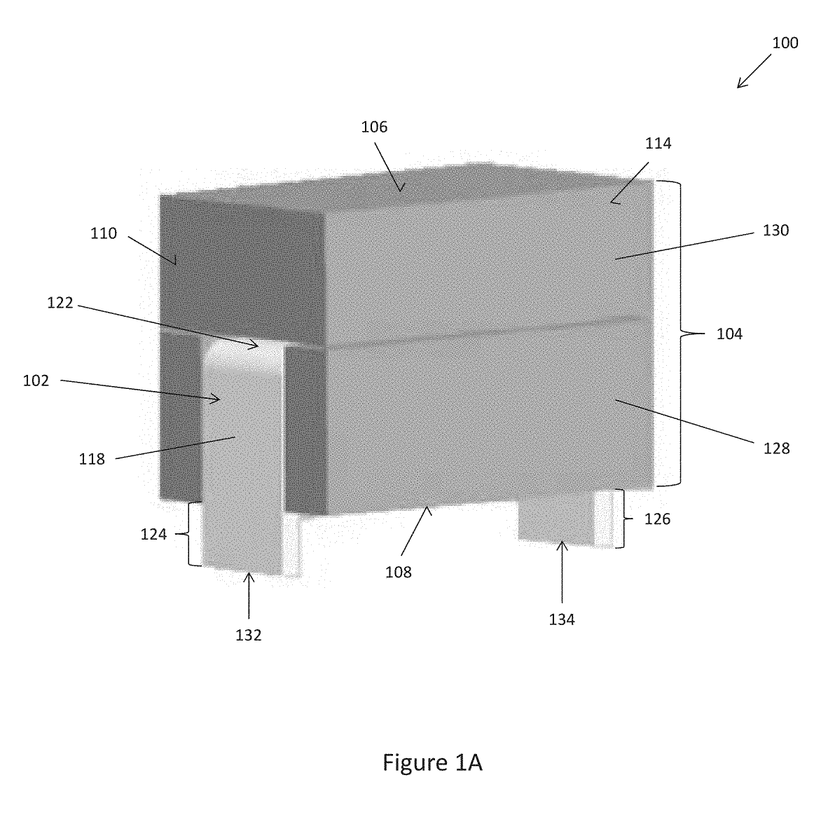

FIG. 1A shows a side perspective view of a surface mount inductor 100 shaped to accommodate a power stage die of a power converter under the inductor 100. FIG. 1B shows a top plan view of the surface mount inductor 100. FIG. 1C shows a bottom plan view of the surface mount inductor 100. FIG. 1D shows a side plan view of the surface mount inductor 100. FIG. 1E shows a front plan view of the surface mount inductor 100. FIG. 1F shows a top plan view of the circuit board footprint for the surface mount inductor 100.

The surface mount inductor 100 comprises an electrical conductor 102 and a magnetic core 104 having top and bottom main faces 106, 108 and side faces 110, 112, 114, 116 extending between the top and bottom main faces 106, 108. The electrical conductor 102 comprises a first section 118 extending along a first one of the side faces 110 of the magnetic core 104, a second section 120 extending along a second one of the side faces 112 opposite the first side face 110, and a third section 122 connecting the first and second 118, 120 sections and extending through the magnetic core 104. The electrical conductor 102 further comprises a first straight lead 124 extending downwards from the first section 118 beyond the bottom main face 108 of the magnetic core 104, and a second straight lead 126 extending downwards from the second section 120 beyond the bottom main face 108 of the magnetic core 104. The magnetic core 104 can include two or more sections 128, 130 between which the third section 122 of the electrical conductor is interposed. The magnetic core sections 128, 130 can be attached to one another e.g. by an adhesive to secure the electrical conductor 102 in place and ensure the straight leads 124, 126 of the conductor 102 are contactable via a standard surface mount process.

The first and second straight leads 124, 126 each have an unbent distal end 132, 134 configured for surface mounting to a circuit board. Also, the first and second straight leads 124, 126 each have a height (D) and a width (F) which allows for the power stage to be mounted to the circuit board at least partly under the magnetic core 104 as will be described later in more detail, meaning that the power stage is partly or completely covered by the inductor 100. For example, one or more sides of the power stage may remain exposed so that pins along this side of the power stage are readily visible. The power stage is not shown in FIGS. 1A through 1F for ease of illustration of the surface mount inductor 100.

The dimensions of the surface mount inductor 100 can vary significantly depending on the size of the power stage die or components at least partly accommodated under the inductor 100. In FIGS. 1B through 1E, the total length of the surface mount inductor 100 is labeled A, the total width is labeled B, and the total height is labeled C. Also in FIGS. 1B through 1E, the height of the straight leads of the electrical conductor is labeled D, the spacing between the straight leads is labeled E, the width of the straight leads is labeled F, and the thickness of the straight leads is labeled G. FIG. 1F which shows an exemplary board footprint for the surface mount inductor 100, in which H represents the outer spacing for the lead footprint on the circuit board, I represents the inner spacing for the lead footprint on the circuit board, and J represents the length for the lead footprint on the circuit board.

The straight leads 124, 126 should be wide enough and thick enough to ensure that the magnetic core 104 can be raised to a given distance above the circuit board so as to provide enough clearance for placing a power stage die under the inductor 100 and so that the inductor 100 remains properly positioned on the circuit board during the surface mount process. For example in the case of the surface mount inductor having a length (A) of about 10 to 11 mm and a width (B) of about 8.5 to 9.5 mm, the height (D) of the straight leads 124, 126 can range from about 1.0 to 1.5 mm, the width (F) of the straight leads 124, 126 can range from about 3.5 to 5.5 mm, and the thickness (G) of the straight leads 124, 126 can range from about 0.8 to 1.0 mm. These dimensional ranges are only intended as illustrative examples. In a broad sense, the dimensions of the straight leads 124, 126 are a function of the overall inductor dimensions which in turn are a function of the dimensions of the power stage die to be at least partly accommodated under the inductor 100. The dimensions of the straight leads 124, 126 can be selected as desired so long as the leads 124, 126 are wide enough and thick enough to ensure that the magnetic core 104 can be raised to a particular distance needed to accommodate a power stage die at least partly under the inductor 100 and so that the inductor 100 remains properly positioned on the circuit board during the surface mount process as explained above. During power stage and inductor assembly on the same side of the board, these components do not touch each other and are not part of a monolithic (or molded in one piece) power module.

In general, the straight leads 124, 126 of the electrical conductor 102 should have the same height (D) to ensure proper surface mounting of the inductor 100. The height (D) of the straight leads 124, 126 must be great enough to accommodate a power stage die at least partly under the surface mount inductor 100. The straight leads 124, 126 extend from the respective first and second sections 118, 120 of the electrical conductor 102 below the bottom main surface 108 of the magnetic core 104 to provide the necessary spacing to accommodate the power stage die. The first straight lead 118 can have the same width (F) as the first section 118 of the electrical conductor 102, and the second straight lead 126 can have the same width as the second section 120 of the electrical conductor 102. In other cases, the straight leads 124, 126 can be wider or narrower than the corresponding section 118/120 of the electrical conductor 102 from which it extends.

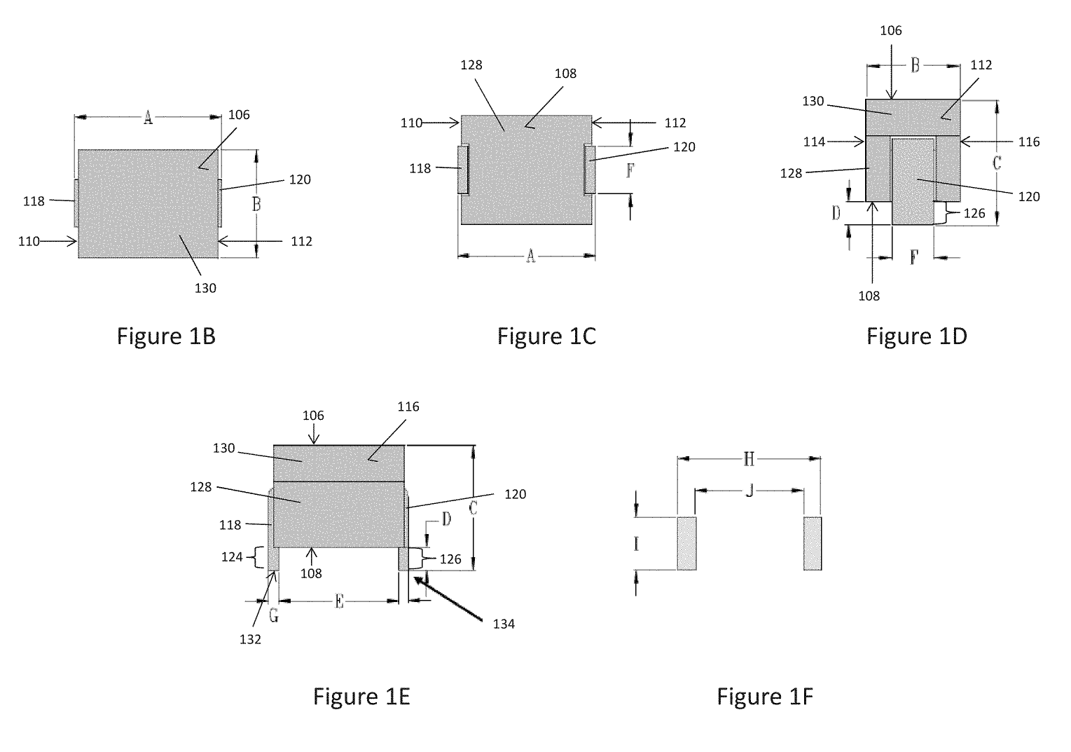

FIG. 2 illustrates one embodiment of the bottom section 128 of the magnetic core 104 included in the surface mount inductor 100 shown in FIGS. 1A through 1E. According to this embodiment, the first side face of 110 the magnetic core 104 has a first channel 200 for receiving the first section 118 of the electrical conductor 102, the second side face 112 of the magnetic core 104 has a second channel 202 for receiving the second section 120 of the electrical conductor 102, and the bottom section 128 of the magnetic core 104 has a third channel 204 for receiving the third section 122 of the electrical conductor 102.

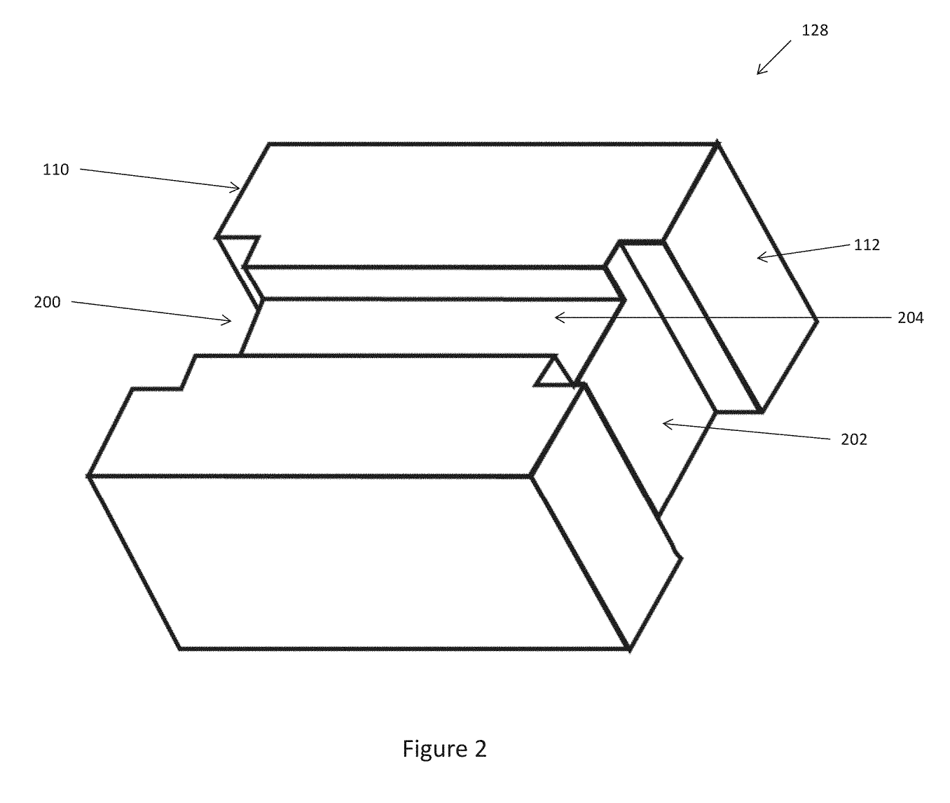

FIGS. 3A through 3D illustrate different views of the electrical conductor 102 included in the surface mount inductor 100 shown in FIGS. 1A through 1E. FIG. 3A shows a top plan view of the electrical conductor 102. FIG. 3B shows a side plan view of the electrical conductor 102. FIG. 30 shows a front plan view of the electrical conductor 102. FIG. 3D shows a side perspective view of the electrical conductor 102. According to this embodiment, the third section 122 of the electrical conductor 102 is narrower than the first and second sections 118, 120. For example, the third section 122 of the electrical conductor 102 can have a width (W1) between 50% and 75% of the width (W2) of the first and second sections 118, 120. The electrical conductor 102 can be shaped like a staple, for example, and have a single continuous construction.

The electrical conductor 102 shown in FIGS. 3A through 3D can be formed by taking a straight metal conductor having a smaller width (W1) in the middle and a larger width (W2) toward the ends, and bending the conductor at the width transition points so that the electrical conductor has a first bend 300 between the first and third sections 118, 122 and a second bend 302 between the second and third sections 120, 122. The width of the electrical conductor 102 is greater between the first bend 300 and the first straight lead 124 and between the second bend 302 and the second straight lead 126 than between the first and second bends 300, 302 according to this embodiment i.e. W2>W1. With such a configuration, the third (middle) section 122 of the electrical conductor 102 provides higher inductance when passing through the magnetic core 104 and the wider end sections 118, 120 provide lower DCR i.e. the inherent resistance in the metal conductor of an inductor. Alternatively, all sections 118, 120, 122 of the electrical conductor 102 adjacent the magnetic core 104 have the same width i.e. W2=W1.

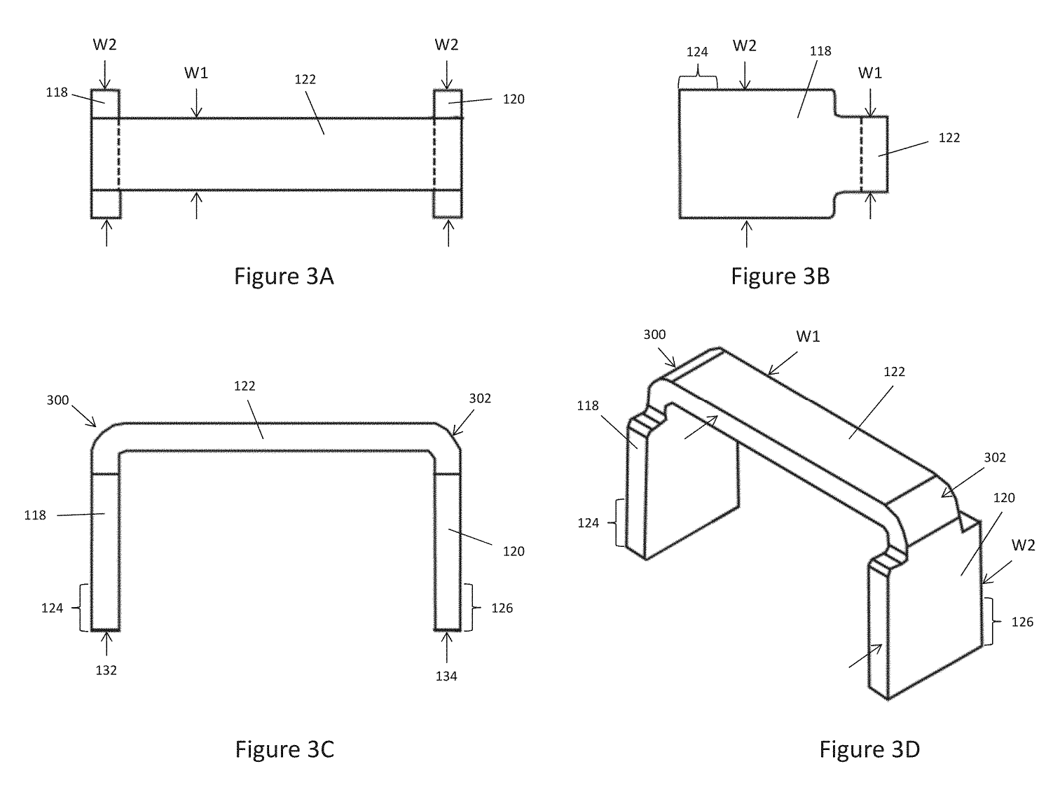

FIG. 4 illustrates a side view of the electrical conductor 102 included in the surface mount inductor 100 shown in FIGS. 1A through 1E, according to another embodiment. In this case, the first section 118 of the electrical conductor which extends along the first side face 110 of the magnetic core 104 does not have a uniform width over its entire length. Instead, the first section 118 of the electrical conductor 102 has a smaller width (W2_{A}) at the end further from the bottom main face 108 of the magnetic core 104 and a larger width (W2_{B}) at the end closer to the bottom main face 108 of the magnetic core 104. The second (opposing) section 120 of the electrical conductor 102 which extends along the second (opposing) side face 112 of the magnetic core 103 also does not have a uniform width over its entire length, but is out of view in FIG. 4.

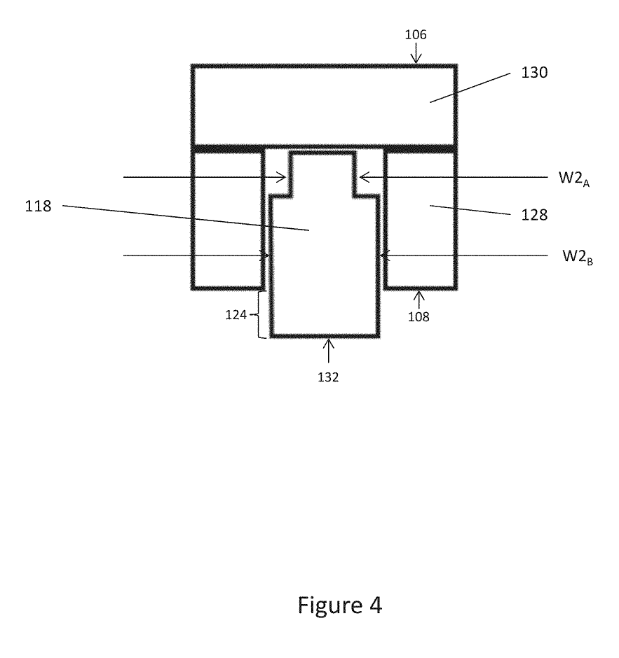

FIG. 5 illustrates a partial view of an embodiment of a power converter assembly 400 that includes one or more of the surface mount inductors described herein. According to this embodiment, the power converter assembly 400 comprises a circuit board 404 such as a PCB having a first main side and a second main side opposite the first side. At least one power stage die 406 of a power converter is attached to the first side of the circuit board 400. In one embodiment, the power converter is a DC-DC converter having a plurality of power stage dies 406 attached to the first side of the circuit board 400. In this case, the DC-DC converter is a multi-phase converter and each of the power stage dies 406 delivers a phase current through an output inductor 100 to a load regulated by the DC-DC converter. The VOUT node of the load is attached to the same side of the circuit board 400 as the power stage dies 406, and connected at the same side or the opposite side of the board 400 with regard to the load. The load can be any type of circuit requiring a regulated voltage such as one or more processors. The load and various components of the power converter such as the output capacitor, controller, etc. are out of view in FIG. 5. These components are not shown in FIG. 5 because their illustration is not necessary to aid in the understating of the present invention.

The left hand side of FIG. 5 illustrates one phase of the multi-phase DC-DC converter prior to attachment of the output inductor 100 to the first side of the circuit board 400, and the right hand side illustrates a second phase after attachment of the corresponding output inductor 100 to the first side of the circuit board 400. Each output inductor 100 is a surface mount inductor of the kind described herein. Also attached to the first side of the circuit board 400 are passive components 402 of the power converter such as input capacitors, output capacitors, resistors, etc. In one embodiment, some of the passive components 402 of the power converter can be accommodated under the output inductors 100. In either case, the passive components 402 and power stage dies 406 are attached to the fist side of the circuit board 400 before the respective output inductors 100. One power stage die 406 is visible in the left hand side of FIG. 5. The footprint for the corresponding output inductor to be mounted to this part of the circuit board corresponds to the solid box labeled ‘PRE’ in FIG. 5. The output inductors 100 are attached to the first side of the circuit board 400 after the passive components 402 and the power stage dies 406. One output inductor 100 is visible in the right hand side of FIG. 5. The footprint for a conventional output inductor with bent leads corresponds to the dashed box labeled ‘CON’ in FIG. 5.

The components attached to the circuit board 400, including the output inductors 100, are electrically connected to various terminals of the power stage dies 406 by electrically conductive vias 408 and/or traces 410, 412 which are part of the circuit board 400. Each output inductor 100 is a surface mount inductor of the kind described herein, and is electrically connected to the output of the corresponding power stage die 406 and disposed over that die 406 on the first side of the circuit board 400, As such, each output inductor 100 has a magnetic core and an electrical conductor which includes a first section extending along a first side face of the magnetic core, a second section extending along an opposing second side face of the magnetic core, and a third section connecting the first and second sections and extending through the magnetic core. Each electrical conductor also includes a first straight lead extending downwards from the first section beyond the bottom main face of the magnetic core and having an unbent distal end configured for surface mounting to the circuit board 400, and a second straight lead extending downwards from the second section beyond the bottom main face of the magnetic core and having an unbent distal end configured for surface mounting to the circuit board 400. The first and second straight leads each have a height and a width which allows for the power stage die 406 mounted to the circuit board 400 at least partly under the magnetic core as previously described herein.

Each surface mount inductor 100 is attached to the first side of the circuit board 400 by attaching the unbent distal end of the straight leads to respective electrically conductive contact regions 410, 412 at the first side of the circuit board 400 after the power stage dies 406 are attached to the same side of the circuit board 400. One of the electrically conductive contact regions 410 is electrically connected to the output (VOUT) of the corresponding power stage die 406. The other electrically conductive contact region 412 is electrically connected to the switched output (VSW) of the power converter.

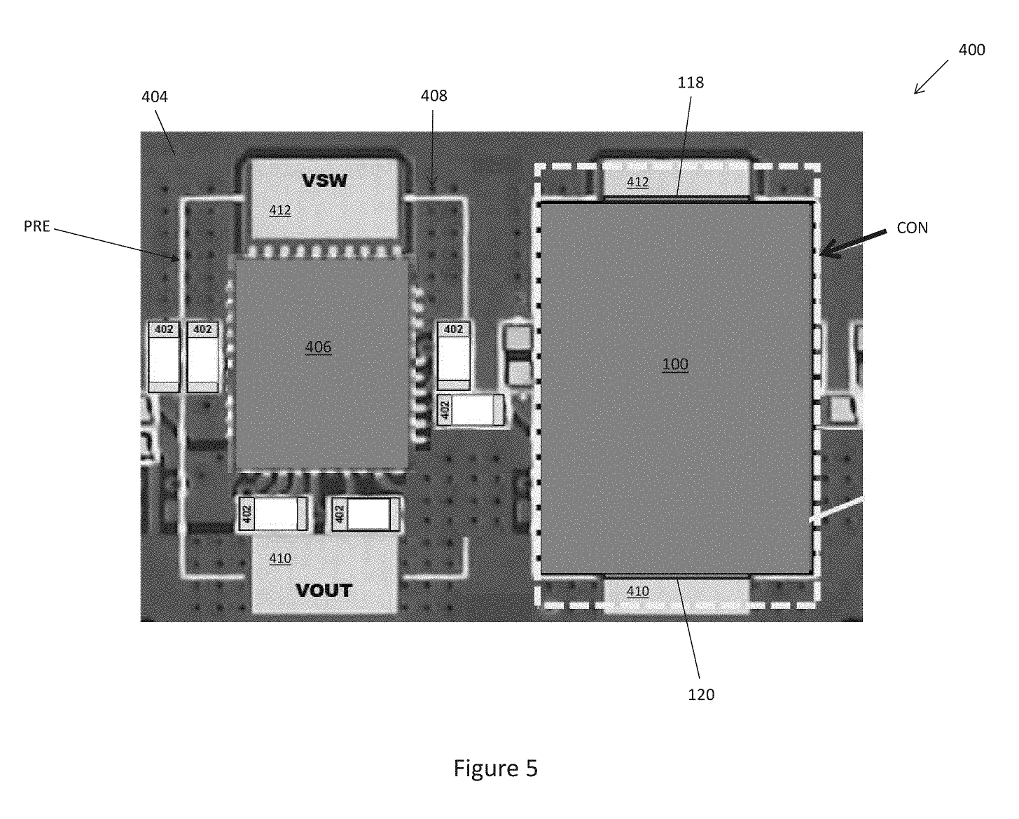

FIG. 6 illustrates a side perspective view of another embodiment of a surface mount inductor 500 shaped to accommodate one or more power stage dies of a power converter under the inductor 500. According to this embodiment, the surface mount inductor 500 is a 2-phase coupled or non-coupled inductor. That is, the surface mount inductor 500 also includes a second electrical conductor 502 spaced apart from the first electrical conductor 102. The first electrical conductor 102 is associated with a first phase of a power stage of a power converter, and the second electrical conductor 502 is associated with a second phase of the powerstage. Similar to the first electrical conductor 102, the second electrical conductor 502 comprises a first section 504 extending along the first side face 110 of the magnetic core 104, a second section (out of view) extending along the second side face 112 of the magnetic core 104, and a third section 506 connecting the first and second sections and extending through the magnetic core 104.

In a non-coupled inductor configuration, the second electrical conductor 502 also comprises a first straight lead 508 extending downwards from the first section 508 beyond the bottom main face 108 of the magnetic core 104 and having an unbent distal end 510 configured for surface mounting to a circuit board, and a second straight lead 512 extending downwards from the second section beyond the bottom main face 108 of the magnetic core 104 and also having an unbent distal end 514 configured for surface mounting to the circuit board. In a two-phase coupled inductor configuration, both electrical conductors 102, 502 enter and exit the magnetic core 104 at the same side of the magnetic material. Respectfully, the other phase electrical conductor (out of view) ending with extended leads of 512 and 126 corresponds to the VSW and VOUT nodes of that second phase. In either configuration, the straight leads 508, 512 of the second electrical conductor 502, like the straight leads 124, 126 of the first electrical conductor 102, each have a height and a width which allows for one or more power stage dies to be mounted to the circuit board at least partly under the magnetic core 104. This concept can be generally extended to an M-phase surface mount inductor.

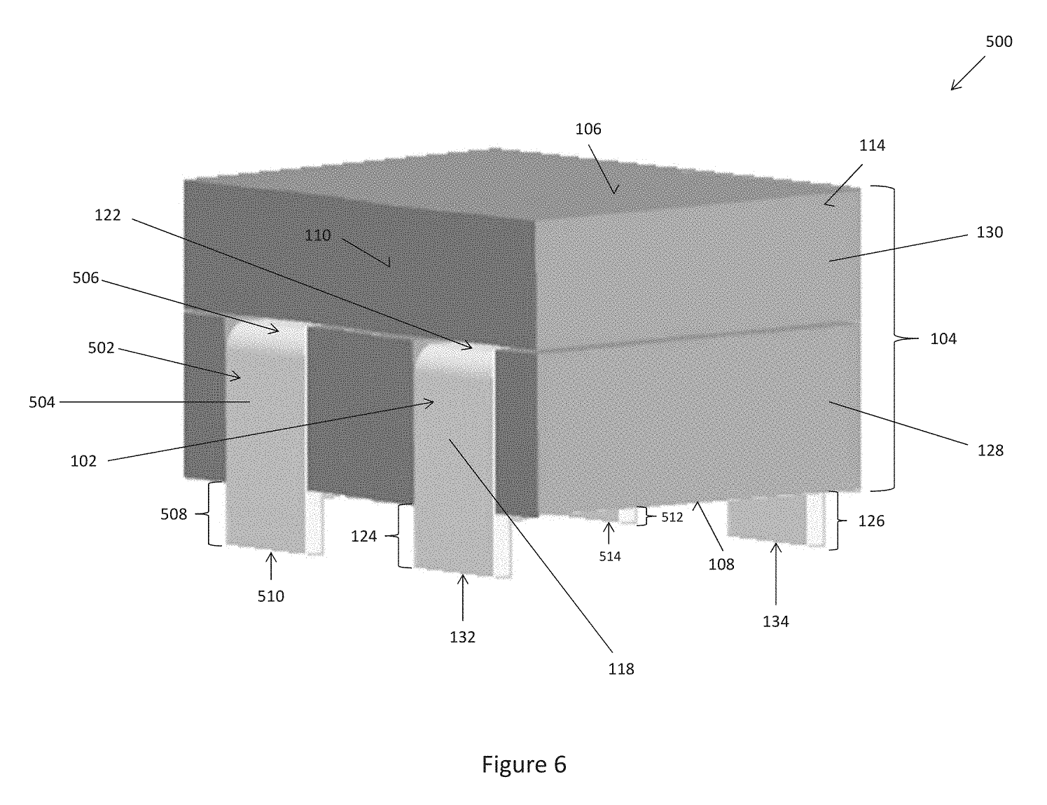

FIG. 7 illustrates a side view of yet another embodiment of a surface mount inductor shaped to accommodate two power stage dies of two power converters under the inductor. The embodiment shown in FIG. 7 is similar to the embodiment shown in FIG. 6. Different, however, each pair of opposing first and second sections of electrical conductors 102, 502 of the 2-phase coupled or non-coupled inductor do not have a uniform width over their respective lengths. Instead, the first section 118, 504 of each electrical conductor 102, 502 which extends along the first side face 110 of the magnetic core 104 has a smaller width (W2_{A1},W2_{A2}) at the end further from the bottom main face 108 of the magnetic core 104 and a larger width (W2_{B1}, W2_{B2}) at the end closer to the bottom main face 108 of the magnetic core 104. The second (opposing) section of each electrical conductor 102, 502 which extends along the second (opposing) side face 112 of the magnetic core 104 also does not have a uniform width over its length, but is out of view in FIG. 7.

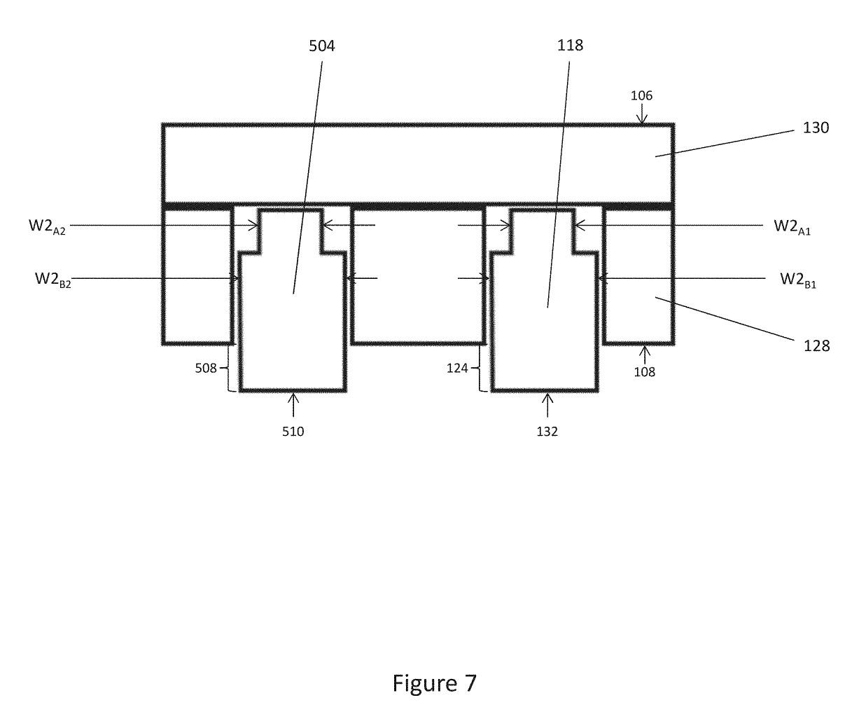

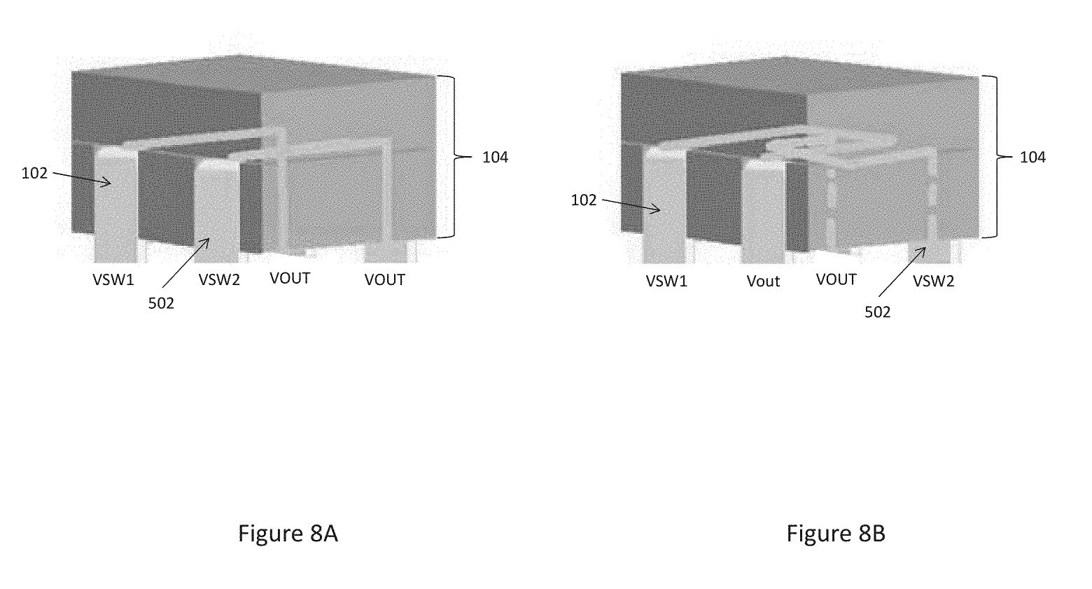

The multi-phase surface mount inductors shown in FIGS. 6 and 7 can be implemented as coupled or non-coupled inductors as explained above. FIG. 8A shows a non-coupled implementation of a 2-phase inductor, in which each electrical conductor 102, 502 enters and exits from opposite sides of the magnetic core 104. FIG. 8B shows a coupled implementation of a 2-phase inductor, in which one electrical conductor 102 enters and exits from one side of the magnetic core 104 and the other electrical conductor 502 enters and exits from the opposite side of the magnetic core 104. The VSW and VOUT nodes of the respective phases are labeled for each terminal of the electrical conductors 102, 502 in FIGS. 8A and 8B. This concept can be generally extended to an M-phase surface mount inductor.

The surface mount inductors described herein have straight leads which are surface mountable and which have sufficient height to allow for a power stage of a power converter to be accommodated at least partly under the inductor. The height of the straight leads depends on the dimensions of the inductor and of the power stage, but in some cases can range from 1.0 to 1.5 mm. During board manufacture, the straight-lead surface mount inductors can be assembled after power stage placement in a single solder reflow or manually as a second step of the component assembly. In the case of a single solder reflow, a visual inspection of the power stage control pins under the inductor is not possible by automated microscope inspection, meaning that an X-Ray machine should be used to inspect the pins covered by the inductors. By manually installing the straight-lead surface mount inductors after the solder reflow process for the power stages and other components of the power converter, than visual optical inspection via microscope is possible before inductor attachment.

Compared to comparable surface mount inductors with bent leads, the straight-lead inductors described herein have a shorter overall inductor length e.g. of about 2 mm for the same type of current application. The straight leads are made extra thick e.g. 0.8 to 1.0 mm thick to prevent the inductor from sliding during solder reflow. The straight leads also are wide enough e,g. 3.5 to 5.5 mm wide so as to significantly lower inductor DCR. For example, DCR in the range of 0.17-19 mΩ saves 1W power at full load for a 5-phase server voltage regulator. The surface mount inductors described herein can be used with server CPUs (central processing units), graphics card GPUs (graphics processing units), telecommunication ASICs (application-specific integrated circuits) and FPGA (field-programmable gate array) applications, etc. to name a few.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures, Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A surface mount inductor for placement over a power stage of a power converter, the surface mount inductor comprising:
a magnetic core having top and bottom main faces and side faces extending between the top and bottom main faces; and
a first electrical conductor, comprising:
a first section extending along a first one of the side faces of the magnetic core;
a second section extending along a second one of the side faces opposite the first side face;
a third section connecting the first and second sections and extending through the magnetic core;
a first straight lead extending downwards from the first section beyond the bottom main face of the magnetic core and having an unbent distal end configured for surface mounting to a circuit board; and
a second straight lead extending downwards from the second section beyond the bottom main face of the magnetic core and having an unbent distal end configured for surface mounting to the circuit board,
wherein the first and second straight leads each have a height and a width which allows for the power stage to be mounted to the circuit board at least partly under the magnetic core.

2. The surface mount inductor of claim 1, wherein the third section of the first electrical conductor is narrower than the first and second sections.

3. The surface mount inductor of claim 2, wherein the third section of the first electrical conductor has a width between 50% and 75% of the width of the first and second sections.

4. The surface mount inductor of claim 1, wherein the first side face of the magnetic core has a channel for receiving the first section of the first electrical conductor, wherein the second side face of the magnetic core has a channel for receiving the second section of the first electrical conductor, and wherein the magnetic core has a channel for receiving the third section of the first electrical conductor.

5. The surface mount inductor of claim 1, wherein the first and second straight leads of the electrical conductor have a thickness between 0.8 mm and 1 mm and a width between 3.5 mm to 5.5 mm.

6. The surface mount inductor of claim 1, wherein the first and second straight leads of the electrical conductor extend beyond the bottom main face of the magnetic core with a height between 1 mm and 1.5 mm so as to provide enough clearance under the surface mount inductor or the power stage to be mounted to the circuit board at least partly under the magnetic core.

7. The surface mount inductor of claim 1, wherein the first electrical conductor has a first bend between the first and third sections and a second bend between the second and third sections, and wherein the width of the first electrical conductor is greater between the first bend and the first straight lead and between the second bend and the second straight lead than between the first and second bends.

8. The surface mount inductor of claim 1, wherein the first straight lead has the same width as the first section of the electrical conductor, and wherein the second straight lead has the same width as the second section of the electrical conductor.

9. The surface mount inductor of claim 1, further comprising a second electrical conductor spaced apart from the first electrical conductor, wherein the first electrical conductor is associated with a first phase of the power stage, wherein the second electrical conductor is associated with a second phase of the power stage, and wherein the second electrical conductor comprises:
a first section extending along the first side face of the magnetic core;
a second section extending along the second side face of the magnetic core;
a third section connecting the first and second sections and extending through the magnetic core;
a first straight lead extending downwards from the first section beyond the bottom main face of the magnetic core and having an unbent distal end configured for surface mounting to the circuit board; and
a second straight lead extending downwards from the second section beyond the bottom main face of the magnetic core and having an unbent distal end configured for surface mounting to the circuit board,
wherein the first and second straight leads of the second electrical conductor each have a height and a width which allows for the power stage to be mounted to the circuit board at least partly under the magnetic core.

10. A power converter assembly, comprising:
a circuit board having a first side and a second side opposite the first side;
a power stage die of a power onverter attached to the first side of the circuit board; and
a surface mount inductor electrically connected to an output of the power stage die and disposed over the power stage die on the first side of the circuit board, the surface mount inductor comprising:
a magnetic core having top and bottom main faces and side faces extending between the top and bottom main faces; and
a first electrical conductor, comprising:
a first section extending along a first one of the side faces of the magnetic core;
a second section extending along a second one of the side faces opposite the first side face;
a third section connecting the first and second sections and extending through the magnetic core;
a first straight lead extending downwards from the first section beyond the bottom main face of the magnetic core and having an unbent distal end surface mounted to the circuit board; and
a second straight lead extending downwards from the second section beyond the bottom main face of the magnetic core and having an unbent distal end surface mounted to the circuit board;
wherein the first and second straight leads each have a height and a width which allows for the powerstage to be mounted to the circuit board at least partly under the magnetic core.

11. The power converter assembly of claim; wherein the third section of the first electrical conductor is narrower than the first and second sections.

12. The power converter assembly of claim 11, wherein the third section of the first electrical conductor has a width between 50% and 75% of the width of the first and second sections.

13. The power converter assembly of claim 10, wherein the first side face of the magnetic core has a channel for receiving the first section of the first electrical conductor, wherein the second side face of the magnetic core has a channel for receiving the second section of the first electrical conductor, and wherein the magnetic core has a channel for receiving the third section of the first electrical conductor.

14. The power converter assembly of claim 10, wherein the first and second straight leads of the electrical conductor have a thickness between 0.8 mm and 1 mm and a width between 3.5 mm to 5.5 mm.

15. The power converter assembly of claim 10, wherein the first and second straight leads of the electrical conductor extend beyond the bottom main face of the magnetic core with a height between 1 mm and 1.5 mm so as to provide enough clearance under the surface mount inductor or the power stage to be mounted to the circuit board at least partly under the magnetic core.

16. The power converter assembly of claim 10, wherein the first electrical conductor has a first bend between the first and third sections and a second bend between the second and third sections, and wherein the width of the first electrical conductor is greater between the first bend and the first straight lead and between the second bend and the second straight lead than between the first and second bends.

17. The power converter assembly of claim 10, wherein the first straight lead has the same width as the first section of the electrical conductor, and wherein the second straight lead has the same width as the second section of the electrical conductor.

18. The power converter assembly of claim 10, wherein the surface mount inductor further comprise a second electrical conductor spaced apart from the first electrical conductor, wherein the first electrical conductor is associated with a first phase of the power stage, wherein the second electrical conductor is associated with a second phase of the power stage, and wherein the second electrical conductor comprises:
a first section extending along the first side face of the magnetic core;
a second section extending along the second side face of the magnetic core;
a third section connecting the first and second sections and extending through the magnetic core;
a first straight lead extending downwards from the first section beyond the bottom main face of the magnetic core and having an unbent distal end surface mounted to the circuit board; and
a second straight lead extending downwards from the second section beyond the bottom main face of the magnetic core and having an unbent distal end surface mounted to the circuit board,
wherein the first and second straight leads of the second electrical conductor each have a height and a width which allows for the power stage to be mounted to the circuit board at least partly under the magnetic core.

19. A method of manufacturing a power converter assembly, the method comprising:
attaching a power stage die of a power converter to a first side of a circuit board; and
attaching a surface mount inductor to the first side of the circuit board so that the surface mount inductor is electrically connected to an output of the power stage die and disposed over the power stage die on the first side of the circuit board, the surface mount inductor comprising a magnetic core and a first electrical conductor, the first electrical conductor comprising: a first section extending along a first side face of the magnetic core; a second section extending along a second side face of the magnetic core; a third section connecting the first and second sections and extending through the magnetic core; a first straight lead extending downwards from the first section beyond a bottom main face of the magnetic core and having an unbent distal end; and a second straight lead extending downwards from the second section beyond the bottom main face of the magnetic core and having an unbent distal end, the first and second straight leads each having a height and a width which allows for the power stage to be mounted to the circuit board at least partly under the magnetic core,
wherein attaching the surface mount inductor to the first side of the circuit board comprises attaching the unbent distal end of the first and second straight leads to respective electrically conductive contact regions at the first side of the circuit board after the power stage die is attached to the first side of the circuit board, one of the electrically conductive contact regions being electrically connected to the output of the power stage die.

20. A multi-phase coupled surface mount inductor for placement over power stages of a power converter, the surface mount inductor comprising:
a magnetic core having top and bottom main faces and side faces extending between the top and bottom main faces;
a first electrical conductor, comprising:
a first section extending along a first one of the side faces of the magnetic core;
a second section extending along the first side face of the magnetic core;
a third section connecting the first and second sections and extending in the magnetic core;
a first straight lead extending downwards from the first section beyond the bottom main face of the magnetic core and having an unbent distal end configured for surface mounting to a circuit board; and
a second straight lead extending downwards from the second section beyond the bottom main face of the magnetic core and having an unbent distal end configured for surface mounting to the circuit board; and
a second electrical conductor, comprising:
a first section extending along a second one of the side faces of the magnetic core opposite the first side face;
a second section extending along the second side face of the magnetic core;
a third section connecting the first and second sections and extending in the magnetic core;
a first straight lead extending downwards from the first section beyond the bottom main face of the magnetic core and having an unbent distal end configured for surface mounting to a circuit board; and
a second straight lead extending downwards from the second section beyond the bottom main face of the magnetic core and having an unbent distal end configured for surface mounting to the circuit board,
wherein the first and second straight leads of each electrical conductor have a height and a width which allows for the power stages to be mounted to the circuit board at least partly under the magnetic core.
